(19) United States
(12) Patent Application Publication
(10) Pub. No.: US 2025/0379417 A1
(43) Pub. Date: Dec. 11, 2025

(54) SEMICONDUCTOR DEVICE

(71) Applicant: Nippon Telegraph and Telephone Corporation, Tokyo (JP)

(72) Inventors: Wataru Kobayashi, Tokyo (JP); Manabu Mitsuhara, Tokyo (JP); Shigeru Kanazawa, Tokyo (JP)

(21) Appl. No.: 18/876,503

(22) PCT Filed: Jun. 21, 2022
(86) PCT No.: PCT/JP2022/024666

§ 371 Date: Dec. 18, 2024

(51) Int. Cl. H01S 5/026; H01S 5/02

(52) U.S. Cl. CPC H01S 5/026; H01S 5/0208

(57) ABSTRACT

A semiconductor device includes a substrate made of a semi-insulating compound semiconductor, a first optical active element on the substrate, a second optical active element on the substrate, and an optical waveguide optically connecting the first optical active element and the second optical active element. Further, optical waveguide is between the first optical active element and the second optical active element, the optical waveguide including a semi-insulating or undoped third lower semiconductor layer.

### CROSS-REFERENCE TO RELATED APPLICATIONS

This application is a national phase entry of PCT Application No. PCT/JP2022/024666, filed on Jun. 21, 2022, which application is hereby incorporated herein by reference.

### TECHNICAL FIELD

The present invention relates to a semiconductor device in which a plurality of optical active elements is integrated.

### BACKGROUND

In optical communication, a light source having a modulation function is used. For example, in optical communication with a relatively short transmission distance of 100 km or less, an electroabsorption-modulator integrated distributed feedback laser (EML) in which an electroabsorption-modulator and a DFB laser are integrated, is used.

In a conventional EML, a DFB laser that generates light as a carrier wave and an EA modulator that modulates the carrier wave are monolithically integrated on a single semiconductor substrate. In this configuration, the semiconductor substrate uses conductive polarity (mainly an n-polar InP substrate). Therefore, the electrical polarity of the substrate of the portion of each integrated element is inevitably short-circuited due to the structure. Therefore, during operation of the DFB laser and the EA modulator, the substrate is GND, a positive voltage is applied to the DFB laser unit, and a negative voltage is applied to the EA modulator. In this configuration, the EA modulator is driven by applying a single-phase modulation signal. For example, one of the electrodes of the EA modulator is connected to GND to perform single-phase driving.

### CITATION LIST

### Non Patent Literature

Non Patent Literature 1: W. Kobayashi et al., “Design and Fabrication of Wide Wavelength Range 25.8-Gb/S, 1.3-μM, Push-Pull-Driven DMLs”, Journal of Lightwave Technology, vol. 32, no. 1, pp. 3-9, 2014.

### SUMMARY

### Technical Problem

Meanwhile, in order to maximize the characteristics of the EA modulator, it is desirable to perform differential driving. This is because differential driving has effects of improving the S/N of the optical waveform by suppressing common mode noise and halving the modulation amplitude voltage applied to each signal line (Non Patent Literature 1). However, in the conventional structure, since the substrate side is short-circuited, the DFB laser is single-phase driven, and the EA modulator cannot be differentially driven. As described above, in the conventional technology, there is a problem that two optical active elements that are monolithically integrated cannot be driven in different methods.

Embodiments of the present invention has been made to solve the above problems, and an object of the present invention is to drive two monolithically integrated optical active elements by different methods.

### Solution to Problem

A semiconductor device according to embodiments of the present invention includes a substrate made of a semi-insulating compound semiconductor, a first optical active element formed on the substrate, the first optical active element including a first lower semiconductor layer of a first conductivity type, a first active layer formed on the first lower semiconductor layer, and an upper semiconductor layer of a second conductivity type formed on the first active layer, a second optical active element formed on the substrate, the second optical active element including a second lower semiconductor layer of a first conductivity type, a second active layer formed on the second lower semiconductor layer, and the upper semiconductor layer formed on the second active layer, an optical waveguide including a semi-insulating or undoped third lower semiconductor layer, a third active layer formed on the third lower semiconductor layer, and the upper semiconductor layer formed on the third active layer, in which the third lower semiconductor layer is formed on the substrate and in contact with the substrate, the optical waveguide is disposed between the first optical active element and the second optical active element, functions as an electrical isolation portion between the first optical active element and the second optical active element, and optically connects the first optical active element and the second optical active element, a first etching stop layer formed between the substrate and the first lower semiconductor layer, and a second etching stop layer formed between the substrate and the second lower semiconductor layer.

### Advantageous Effects

As described above, according to embodiments of the present invention, the first optical active element and the second optical active element are formed on the substrate including the semi-insulating compound semiconductor via the etching stop layer, and the optical waveguide functioning as the electrical isolation portion is provided between the first optical active element and the second optical active element, so that the two monolithically integrated optical active elements can be driven by different methods.

### BRIEF DESCRIPTION OF THE DRAWINGS

FIG. 1 is a cross-sectional view illustrating a configuration of a semiconductor device according to an embodiment of the present invention.

FIG. 2A is a distribution diagram illustrating a calculation result of a field intensity distribution of a cross section perpendicular to a waveguide direction in a first optical active element 102.

FIG. 2B is a distribution diagram illustrating a calculation result of a field intensity distribution of a cross section perpendicular to a waveguide direction in the first optical active element 102.

FIG. 2C is a distribution diagram illustrating a calculation result of a field intensity distribution of a cross section perpendicular to a waveguide direction in the first optical active element 102.

FIG. 3 is a configuration diagram illustrating a configuration of a model used for calculation of an electric resistance value by a third lower semiconductor layer 141 in an optical waveguide 104.

FIG. 4A is a configuration diagram illustrating a configuration of a model used in a simulation performed for optical coupling between the first optical active element 102 and the optical waveguide 104.

FIG. 4B is a characteristic diagram illustrating a calculation result of an optical coupling coefficient with respect to a variation Δz of a thickness z of a third lower semiconductor layer 141 of the optical waveguide 104.

FIG. 5A is an explanatory diagram illustrating a difference ΔW between a waveguide width WLD of the first optical active element 102 and a waveguide width Wiso of the optical waveguide 104.

FIG. 5B is a characteristic diagram illustrating a calculation result of the optical coupling efficiency with respect to the difference ΔW in the waveguide width.

FIG. 6A is a cross-sectional view of a surface parallel to a waveguide direction, illustrating a state of the semiconductor device in an intermediate process for illustrating a manufacturing method of the semiconductor device according to the embodiment of the present invention.

FIG. 6B is a cross-sectional view of a surface parallel to a waveguide direction, illustrating a state of the semiconductor device in an intermediate process for illustrating a manufacturing method of the semiconductor device according to the embodiment of the present invention.

FIG. 6C is a cross-sectional view of a surface parallel to a waveguide direction, illustrating a state of the semiconductor device in an intermediate process for illustrating a manufacturing method of the semiconductor device according to the embodiment of the present invention.

FIG. 6D is a cross-sectional view of a surface parallel to a waveguide direction, illustrating a state of the semiconductor device in an intermediate process for illustrating a manufacturing method of the semiconductor device according to the embodiment of the present invention.

FIG. 6E is a cross-sectional view of a surface parallel to a waveguide direction, illustrating a state of the semiconductor device in an intermediate process for illustrating a manufacturing method of the semiconductor device according to the embodiment of the present invention.

FIG. 6F is a cross-sectional view of a surface parallel to a waveguide direction, illustrating a state of the semiconductor device in an intermediate process for illustrating a manufacturing method of the semiconductor device according to the embodiment of the present invention.

FIG. 6G is a cross-sectional view of a surface perpendicular to a waveguide direction, illustrating a state of the semiconductor device in an intermediate process for illustrating a manufacturing method of the semiconductor device according to the embodiment of the present invention.

FIG. 6H is a cross-sectional view of a surface parallel to a waveguide direction, illustrating a state of the semiconductor device in an intermediate process for illustrating a manufacturing method of the semiconductor device according to the embodiment of the present invention.

FIG. 6I is a cross-sectional view of a surface perpendicular to a waveguide direction, illustrating a state of the semiconductor device in an intermediate process for illustrating a manufacturing method of the semiconductor device according to the embodiment of the present invention.

FIG. 6J is a cross-sectional view of a surface perpendicular to a waveguide direction, illustrating a state of the semiconductor device in an intermediate process for illustrating a manufacturing method of the semiconductor device according to the embodiment of the present invention.

FIG. 7A is a cross-sectional view of a surface parallel to a waveguide direction, illustrating a state of the semiconductor device in an intermediate process for illustrating another manufacturing method of the semiconductor device according to the embodiment of the present invention.

FIG. 7B is a cross-sectional view of a surface perpendicular to a waveguide direction, illustrating a state of the semiconductor device in an intermediate process for illustrating another manufacturing method of the semiconductor device according to the embodiment of the present invention.

FIG. 7C is a cross-sectional view of a surface parallel to a waveguide direction, illustrating a state of the semiconductor device in an intermediate process for illustrating another manufacturing method of the semiconductor device according to the embodiment of the present invention.

FIG. 7D is a cross-sectional view of a surface perpendicular to a waveguide direction, illustrating a state of the semiconductor device in an intermediate process for illustrating another manufacturing method of the semiconductor device according to the embodiment of the present invention.

### DETAILED DESCRIPTION OF ILLUSTRATIVE EMBODIMENTS

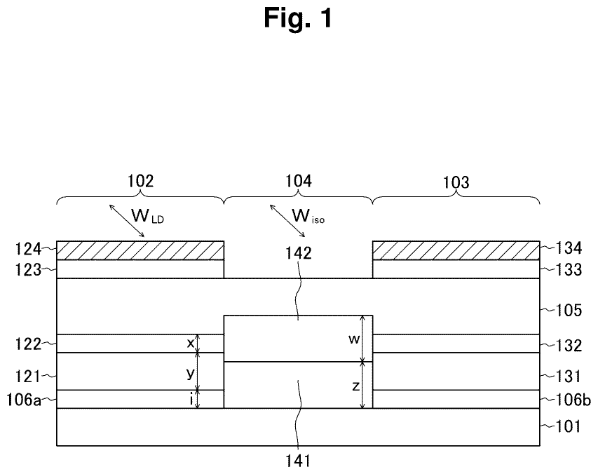

Hereinafter, a semiconductor device according to an embodiment of the present invention will be described with reference to FIG. 1. The semiconductor device includes a substrate 101 made of a semi-insulating compound semiconductor, a first optical active element formed on the substrate 101, a second optical active element 103 formed on the substrate 101, and an optical waveguide 104 optically connecting a first optical active element 102 and the second optical active element 103. The substrate 101 can be formed of, for example, InP (SI-InP) that is given high resistance by doping it with Fe. Further, the substrate 101 can have a (001) plane of InP as a main surface. FIG. 1 illustrates a cross section parallel to a waveguide direction of light as a carrier wave.

Further, the first optical active element 102 is formed on a first etching stop layer 106a, and the second optical active element 103 is formed on a second etching stop layer 106b. The first etching stop layer 106a and the second etching stop layer 106b can include, for example, undoped InGaAsP (band gap wavelength: 1.1 μm). In addition, the first etching stop layer 106a and the second etching stop layer 106b can have a thickness of about 10 nm. The optical waveguide 104 is formed in contact with the substrate 101.

The first optical active element 102 includes a first lower semiconductor layer 121 of a first conductivity type, a first active layer 122 formed on the first lower semiconductor layer 121, and an upper semiconductor layer 105 of a second conductivity type formed on the first active layer 122. The upper semiconductor layer 105 functions as an upper cladding. The first lower semiconductor layer 121 is formed on and in contact with the first etching stop layer 106a. In addition, in the first optical active element 102, a first contact layer 123 is formed on the upper semiconductor layer 105, and a first p-electrode 124 is formed on the first contact layer 123.

The first lower semiconductor layer 121 can be formed of, for example, n-type InP (doped amount 1E18). In addition, the first lower semiconductor layer 121 can have a thickness of about 800 nm. The first active layer 122 can be formed of, for example, InGaAsP or InGaAlAs. In addition, the first active layer 122 can have a thickness of about 280 nm. The upper semiconductor layer 105 can be formed of p-type InP, for example. The first contact layer 123 can be formed of, for example, InGaAs into which a p-type impurity is introduced at a high concentration. The first optical active element 102 can be, for example, a semiconductor laser.

The second optical active element 103 includes a second lower semiconductor layer 131 of a first conductivity type, a second active layer 132 formed on the second lower semiconductor layer 131, and an upper semiconductor layer 105 formed on the second active layer 132. The second lower semiconductor layer 131 is formed in contact with the second etching stop layer 106b. In addition, in the second optical active element 103, a second contact layer 133 is formed on the upper semiconductor layer 105, and a second p-electrode 134 is formed on the second contact layer 133.

The second lower semiconductor layer 131 can be formed of n-type InP, for example. The second active layer 132 can be formed of, for example, InGaAsP or InGaAlAs. In addition, the second active layer 132 can have a thickness of about 280 nm. The second contact layer 133 can be formed of, for example, InGaAs into which a p-type impurity is introduced at a high concentration. The second optical active element 103 can be, for example, an electric field absorption type optical modulator (EA modulator).

In addition, the first active layer 122 and the second active layer 132 can have a multiple quantum well structure (MQW structure). The first active layer 122 and the second active layer 132 indicate portions including the MQW structure and the upper and lower optical confinement layers (SCH), and also function as cores of the waveguide structure.

As is well known, the first etching stop layer 106a and the second etching stop layer 106b are formed of materials different from those of the first lower semiconductor layer 121 and the second lower semiconductor layer 131.

The optical waveguide 104 includes a semi-insulating or undoped third lower semiconductor layer 141, a third active layer 142 formed on the third lower semiconductor layer 141, and the upper semiconductor layer 105 formed on the third active layer 142. The third lower semiconductor layer 141 is formed on and in contact with the substrate 101. The third active layer 142 functions as a core of the optical waveguide 104. In the optical waveguide 104, the third lower semiconductor layer 141 and the upper semiconductor layer 105 function as claddings. The third lower semiconductor layer 141 can be formed of i-type InP or high-resistance InP. The third active layer 142 can be formed of, for example, InGaAsP.

The optical waveguide 104 is disposed between the first optical active element 102 and the second optical active element 103 on the substrate 101, functions as an electrical isolation portion between the first optical active element 102 and the second optical active element 103, and optically connects the first optical active element 102 and the second optical active element 103.

Furthermore, in this example, the upper semiconductor layer 105 is commonly formed in the first optical active element 102, the second optical active element 103, and the optical waveguide 104.

Furthermore, a thickness W of the third active layer 142 is equal to or larger than a thickness x of the first active layer 122 and the second active layer 132. The total thickness (W+z) of the third lower semiconductor layer 141 and the third active layer 142 can be equal to or larger than the total thickness (x+y+i) of the first etching stop layer 106a, the first active layer 122, and the first lower semiconductor layer 121 and the total thickness (x+y+i) of the second etching stop layer 106b, the second lower semiconductor layer 131, and the second active layer 132. In addition, a width (WISO) of the third active layer 142 in the waveguide direction can be equal to or larger than widths (WLD) of the first active layer 122 and the second active layer 132 in the waveguide direction.

In the semiconductor device according to the embodiment, the first optical active element 102 is DC-driven, and the second optical active element 103 can be operated by applying a differential modulation signal between the second lower semiconductor layer 131 and the upper semiconductor layer 105 in the region of the second optical active element 103. The laser light emitted by driving the first optical active element 102 which is a semiconductor laser is guided by the optical waveguide 104 and modulated by the second optical active element 103 which is a differentially driven EA modulator.

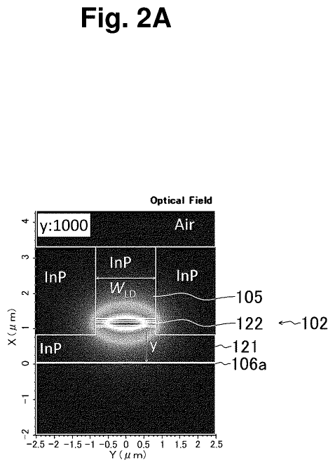

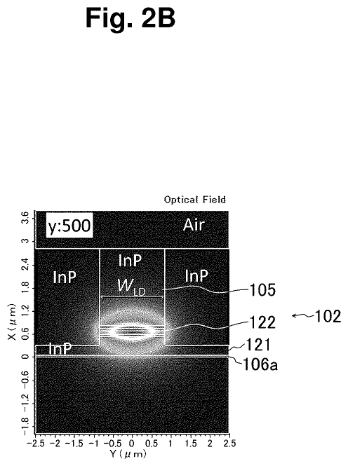

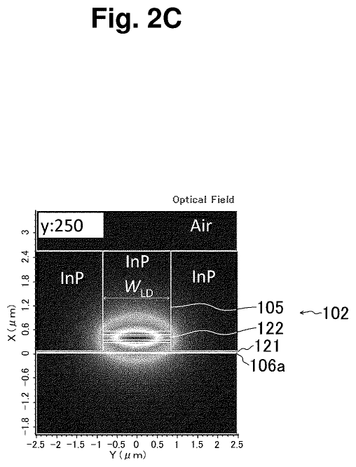

Here, the above-described dimensions will be described in more detail. First, the result of calculating the electric field intensity distribution to estimate the optimum value of the value of the thickness y of the first lower semiconductor layer 121 will be described with reference to FIGS. 2A, 2B, and 2C. FIGS. 2A, 2B, and 2C illustrate the calculation result of the electric field intensity distribution of the cross section perpendicular to the waveguide direction in the first optical active element 102 (second optical active element 103). For this calculation, calculation software “APSS” (Version: 2.3 g, manufactured by APOLLO, INC.) was used.

White lines in FIGS. 2A, 2B, and 2C represent outlines of the calculated structure. The distribution indicated by shading in the drawing indicates the distribution of the electric field intensity. The densest portion of the central portion of the first active layer 122 has the strongest field strength. Areas further away from this and with lower concentration have the weakest field strength.

As an example, the waveguide width WLD was 1.7 μm. A structure in which the waveguide was embedded with the InP material was calculated. In addition, FIG. 2A illustrates a result of calculation for a case where y is 1000 nm. FIG. 2B is a result of calculation for a case where y is 500 nm. FIG. 2C illustrates a result of calculation for a case where y is 250 nm. Furthermore, the thickness x of the first active layer 122 was 300 nm. In addition, the compound semiconductor constituting the first active layer 122 was a compound semiconductor having a band gap wavelength of 1.3 μm. In addition, the first etching stop layer 106a (second etching stop layer 106b) was formed of a semiconductor having a composition of a band gap wavelength of 1.1 μm and had a thickness of 30 nm.

When y is 250, the electric field intensity distribution leaks into the etching stop layer 106. On the other hand, when y is 1000, leakage of the electric field intensity distribution to the etching stop layer 106 can be suppressed. Since the first etching stop layer 106a is formed of a material different from InP constituting the first lower semiconductor layer 121, the second lower semiconductor layer 131, and the third lower semiconductor layer 141, the refractive index thereof is higher than that of InP. Therefore, if the value of y is not set to a sufficient value, the electric field intensity distribution of the first optical active element 102 (second optical active element 103) may be optically coupled to the first etching stop layer 106a, resulting in deterioration of characteristics.

In order to maintain the characteristics of the first optical active element 102 (second optical active element 103), it is necessary for the electric field intensity distribution to suppress exuding into the first etching stop layer 106a (second etching stop layer 106b). The amount of leakage into the first etching stop layer 106a can be calculated by calculating an optical confinement factor I of the first etching stop layer 106a. Γ is 0.00023 for y=1000 nm, 0.00089 for y=750 nm, 0.0034 for y=500 nm each, and 0.0123 for y=250 nm. When y=500 nm, the thickness is 0.01 or less, and it is possible to sufficiently suppress exudation.

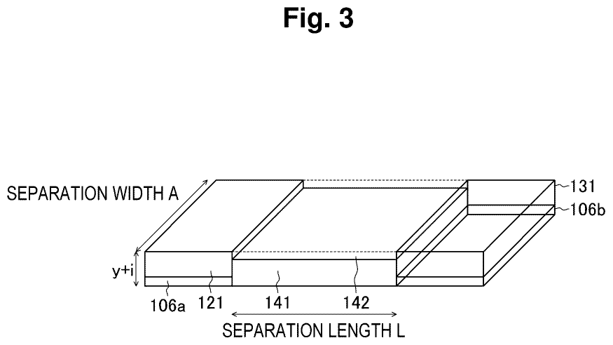

Next, the electric resistance value of the third lower semiconductor layer 141 in the optical waveguide 104 will be described. As illustrated in FIG. 3, a state is considered in which the third lower semiconductor layer 141 and a part of the third active layer 142 are inserted between the first lower semiconductor layer 121 and the second lower semiconductor layer 131 and between the first etching stop layer 106a and the second etching stop layer 106b. The resistance value in this case is obtained.

The thickness of the first lower semiconductor layer 121 is denoted by y, the thickness of the first etching stop layer 106a is denoted by i, the width of the first lower semiconductor layer 121 (first active layer 122) in the direction perpendicular to the waveguide direction is denoted by A, and the length of the third lower semiconductor layer 141 in the waveguide direction is denoted by L. The separation resistance R between the first optical active element 102 and the second optical active element 103 sandwiching the optical waveguide 104 can be expressed by “R=ρ×L/{A×(y+i)}” with the resistivity as ρ.

In order to realize stable operation of the first optical active element 102 and the second optical active element 103, the separation resistance needs to be 10 kΩ or more. A separation width A needs to be 300 μm or more for forming electrodes of the first optical active element 102 and the second optical active element 103. A separation length L needs to be about 250 μm in order to separate the first contact layer 123 and the second contact layer 133 in the upper portion of the upper semiconductor layer 105 of the optical waveguide 104 by, for example, etching processing or the like. The thinner the y+i is, the more the separation resistance can be maintained. However, as described above, since there is leakage of the electric field intensity distribution, the y cannot be set to 500 nm or less.

As a result of the calculation, in order to secure a resistance of 10 kΩ as the separation resistance R, y+i needs to be 1000 nm or less. In this calculation, the third lower semiconductor layer 141 is formed of undoped InP, and in the first lower semiconductor layer 121 and the second lower semiconductor layer 131, n-polarity impurities of about 1E15 [cm-3] are assumed. In this case, the resistivity of the third lower semiconductor layer 141 is 1.3 Ωcm.

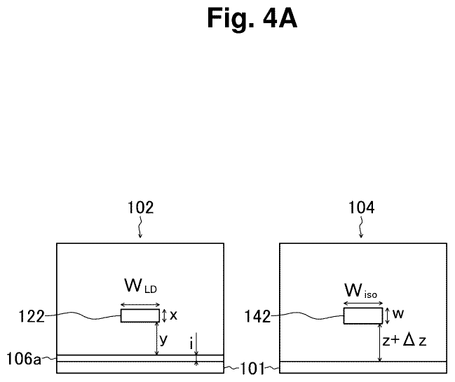

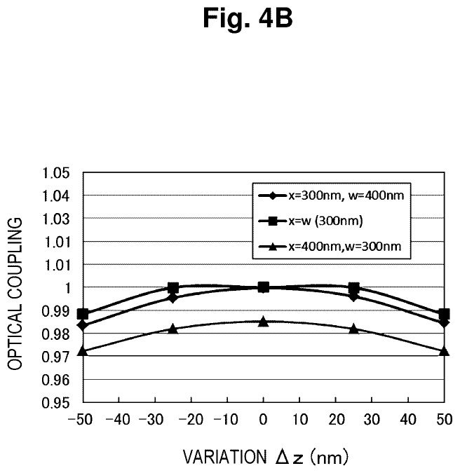

Next, the optical waveguide 104 will be described. High optical coupling is generally required between the first optical active element 102 and the optical waveguide 104. A simulation result of the optical coupling will be described. First, in the simulation, the model illustrated in FIG. 4A was used.

In manufacturing the semiconductor device, first, each semiconductor layer constituting the first optical active element 102 and the second optical active element 103 is crystal-grown, and a part of the crystal-grown semiconductor layer (region to be the optical waveguide 104) is removed by etching. Thereafter, a semiconductor layer constituting the optical waveguide 104 as the electrical isolation portion is crystal-grown in the removed region. Therefore, w and z of the optical waveguide 104 illustrated in FIG. 4A vary during manufacturing. Here, the relationship among x, y, w, z, WLD, and Wiso having a high tolerance capable of maintaining optical coupling with respect to such variations during manufacturing is illustrated by calculation.

FIG. 4B illustrates a calculation result of the optical coupling coefficient with respect to the variation Az of the thickness z of the third lower semiconductor layer 141 of the optical waveguide 104. Calculation was performed as WLD=Wiso (1.7 μm). As illustrated in FIG. 4B, the case of x=w shows the highest coupling coefficient. Although it is not easy to have exactly the same thickness in terms of manufacturing, a state of deterioration of optical coupling from this condition is examined assuming that x=w is the best. The value is set to have tolerance to the variation of the thickness at the time of manufacture. From FIG. 4B, it can be seen that a higher coupling can be maintained by designing w to be the same thickness or thicker than x.

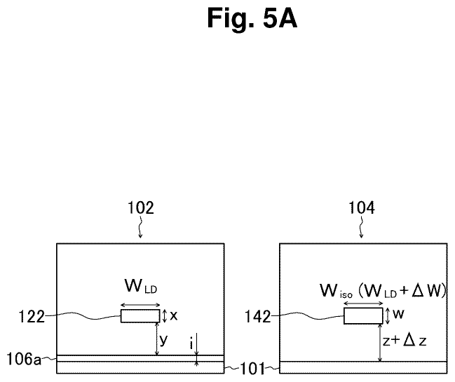

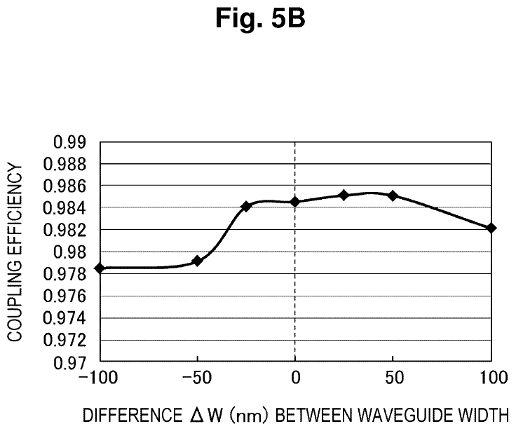

Next, the waveguide width and the optical coupling efficiency will be described. As illustrated in FIG. 5A, a case where there is a difference of ΔW between the waveguide width WLD of the first optical active element 102 and the waveguide width Wiso of the optical waveguide 104 is considered. FIG. 5B illustrates a calculation result of the optical coupling efficiency with respect to the difference AW in the waveguide width. Calculation for x=300 nm, W=400 nm, Δz=50 nm, and WLD=1.7 μm is shown. As illustrated in FIG. 5B, the coupling efficiency increases as Wiso is slightly wider than WLD. It is found that when ΔW is about 25 to 50 nm, the coupling efficiency is maximized.

From the results of FIGS. 4B and 5B, it is found that when w>x and WLD≤Wiso, a variation in thickness at the time of manufacturing can be absorbed and high coupling efficiency can be maintained.

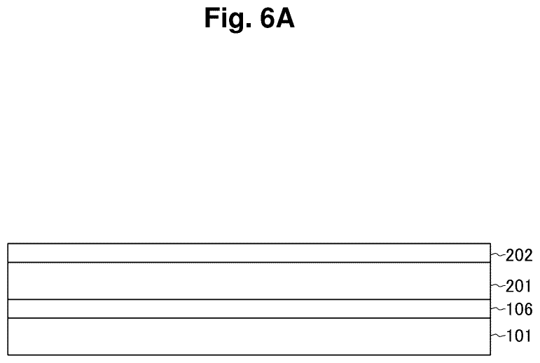

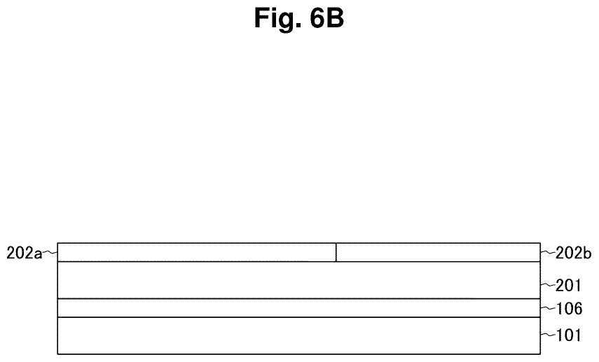

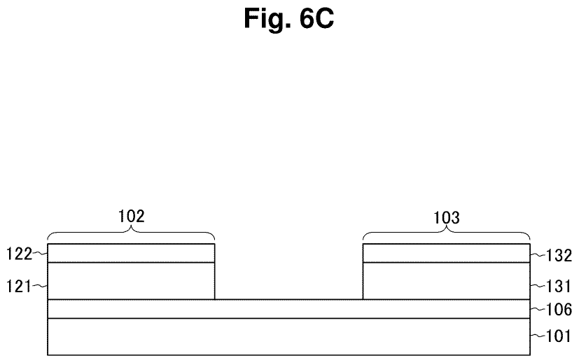

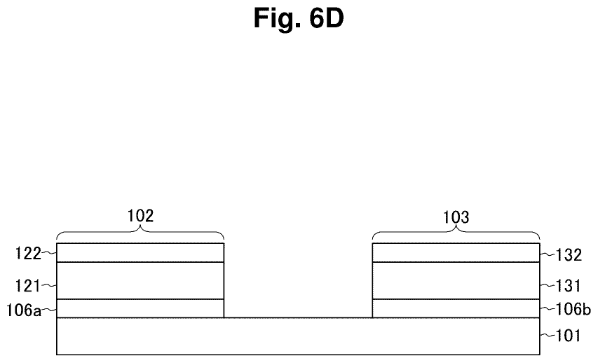

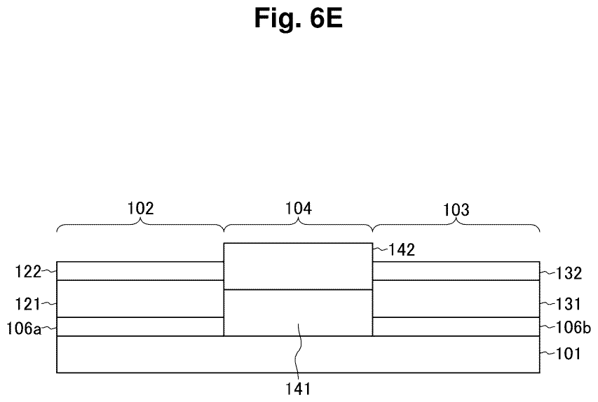

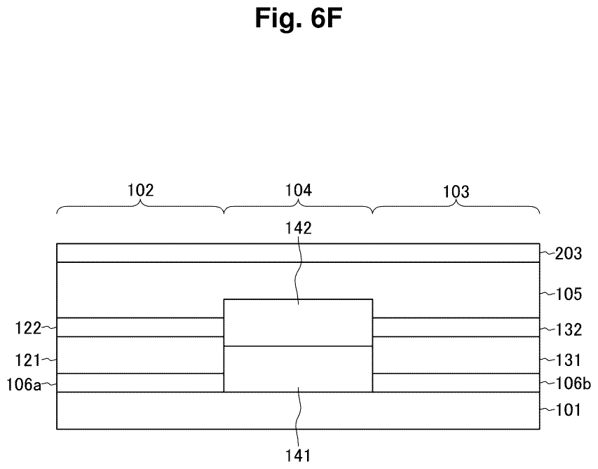

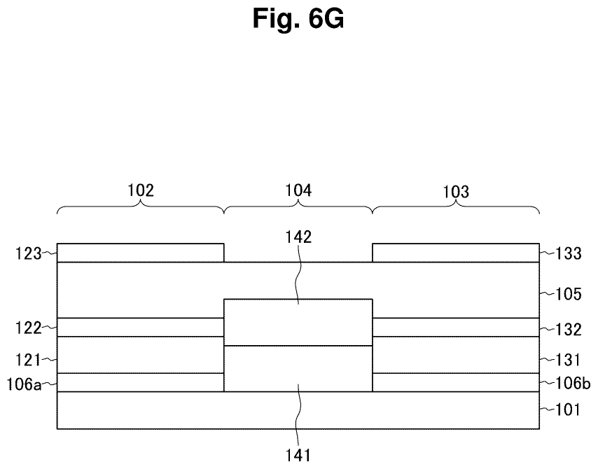

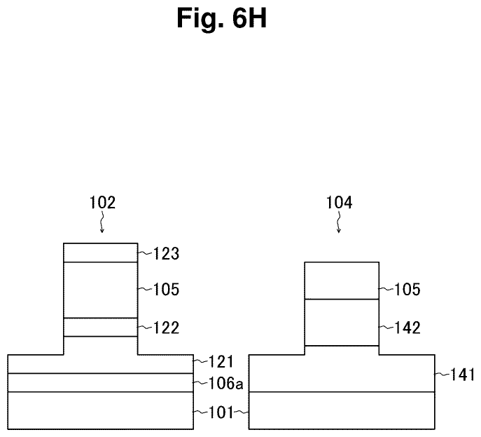

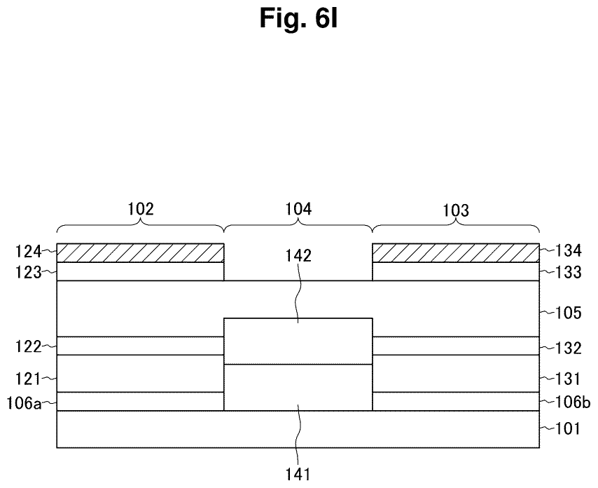

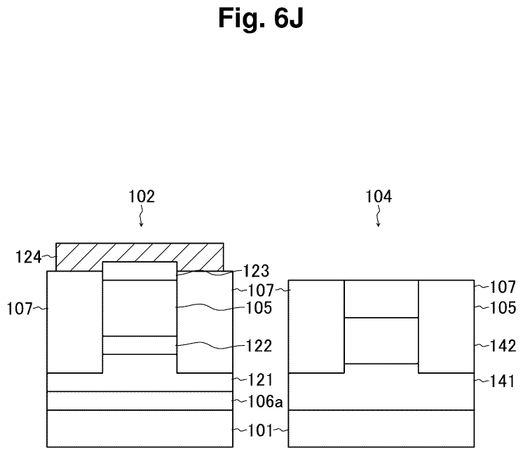

Next, a method for manufacturing a semiconductor device according to an embodiment of the present invention will be described with reference to FIGS. 6A to 6J.

First, as illustrated in FIG. 6A, n-type InGaAsP is crystal-grown on a substrate 101 made of SI-InP to form an etching stop layer 106 having a thickness of 100 nm. The InGaAsP that undergoes the crystal growth has a composition that achieves a band gap wavelength of 1.2 μm, and the n-type impurity has a doping amount of 1E18. Subsequently, the n-type InP (doping amount 1E18) is crystal-grown to form an InP layer 201 having a thickness of 800 nm. Subsequently, the active layer 202 formed of the InGaAsP and having a thickness of 250 nm is formed (crystal growth).

Next, by removing the active layer 202 in the region to be the second optical active element 103, as illustrated in FIG. 6B, the active layer 202a is formed, and an active layer 202b having a thickness of 280 nm is formed (crystal growth) by the InGaAsP at the removed portion, and the active layer 202a and the active layer 202b are butt-joined in the waveguide direction (a butt joint process). The active layer 202a and the active layer 202b have a multiple quantum well structure (MQW structure), and have the above-described thicknesses including the upper and lower optical confinement layers (SCH) of the MQW structure. Note that the active layer 202a and the active layer 202b can also include InGaAlAs.

Next, predetermined regions of the active layer 202a, the active layer 202b, and the InP layer 201 are removed by etching processing using a mask pattern (not illustrated) formed by a known photolithography technique, so that the first lower semiconductor layer 121 and the first active layer 122 of the first optical active element 102 are formed, and the second lower semiconductor layer 131 and the second optical active element 103 of the second optical active element 103 are formed, as illustrated in FIG. 6C. A region between the first optical active element 102 and the second optical active element 103 is a region forming the optical waveguide 104. The above-described etching process can be performed by selective wet etching using the etching stop layer 106 as an etching stop layer.

Next, the etching stop layer 106 is etched by selective wet etching using the substrate 101 as an etching stop layer by further etching using the above-described mask pattern (not illustrated), and the first etching stop layer 106a and the second etching stop layer 106b are formed as illustrated in FIG. 6D.

Next, as illustrated in FIG. 6E, the third lower semiconductor layer 141 and the third active layer 142 of the optical waveguide 104 are formed by crystal growth. The third lower semiconductor layer 141 can be made of undoped InP and formed to have a thickness of about 800 nm, and the third active layer 142 can be formed to have a thickness of about 400 nm.

Next, as illustrated in FIG. 6F, the p-type InP is crystal-grown to a thickness of about 1500 nm to form the upper semiconductor layer 105, and the InGaAs is crystal-grown to a thickness of about 300 nm to form the contact layer 203.

Next, the contact layer 203 in the region of the optical waveguide 104 is removed by etching processing using a mask pattern (not illustrated) formed by a known photolithography technique, so that the first contact layer 123 of the first optical active element 102 is formed and the second contact layer 133 of the second optical active element 103 is formed as illustrated in FIG. 6G. The first contact layer 123 and the second contact layer 133 are electrically separated from each other in a plane direction parallel to the surface of the upper semiconductor layer 105.

Next, as illustrated in FIG. 6H, waveguides of the respective portions are formed by etching processing using a mask pattern (not illustrated) formed by a known photolithography technique. In the first optical active element 102 (the second optical active element 103), the width of the ridge waveguide structure is 1.7 μm, and in the optical waveguide 104, the width of the ridge waveguide structure is 1.9 μm. The above-described change in dimension is realized by changing the width of the portion of the ridge waveguide structure in the photomask for forming the above-described mask pattern. In this processing, the first lower semiconductor layer 121 (second lower semiconductor layer 131) and the third lower semiconductor layer 141 are left to some extent on both sides of the ridge waveguide structure.

Next, as illustrated in FIGS. 6I and 6J, the InP as a semi-insulating material is crystal-regrown on the first lower semiconductor layer 121 (second lower semiconductor layer 131) and the third lower semiconductor layer 141 left on both sides of the ridge waveguide structure, so that the ridge waveguide structure is embedded with an embedding layer 107. Thereafter, the first p-electrode 124 is formed on the first contact layer 123, and the second p-electrode 134 is formed on the second contact layer 133. Although not illustrated, a first n-electrode electrically connected to the first lower semiconductor layer 121 is formed, and a second n-electrode electrically connected to the second lower semiconductor layer 131 is formed.

In the semiconductor device produced as described above, the electrical resistance between the p-electrode and the n-electrode of the first optical active element 102 as a laser and the p-electrode and the n-electrode of the second optical active element 103 as an EA modulator is 10 kΩ or more. Electric separation between n-electrodes, which cannot be achieved by elements integrated on a conventional n-substrate, can be achieved. In addition, the optical coupling efficiency of the first optical active element 102 serving as the laser unit and the optical waveguide 104 can be a good value of about 98% in calculation.

As a result of applying the differential modulation signal to the second optical active element 103 serving as the EA modulator of the manufactured semiconductor device, it was confirmed that the stable operation of the first optical active element 102 serving as the laser unit and the clear waveform opening of the second optical active element 103 reflected the high electrical resistance described above.

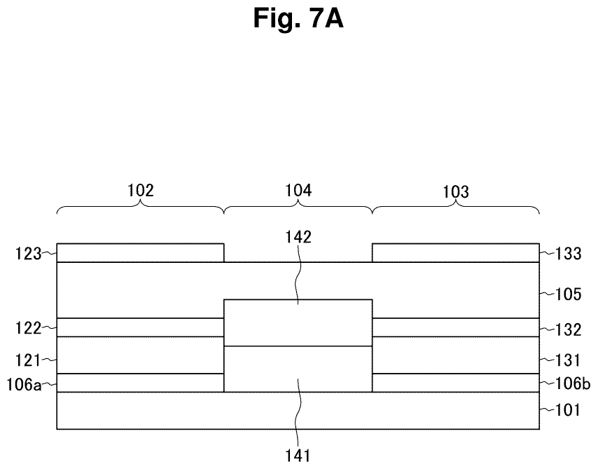

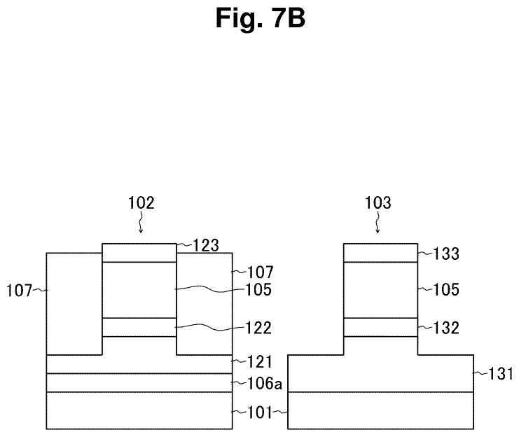

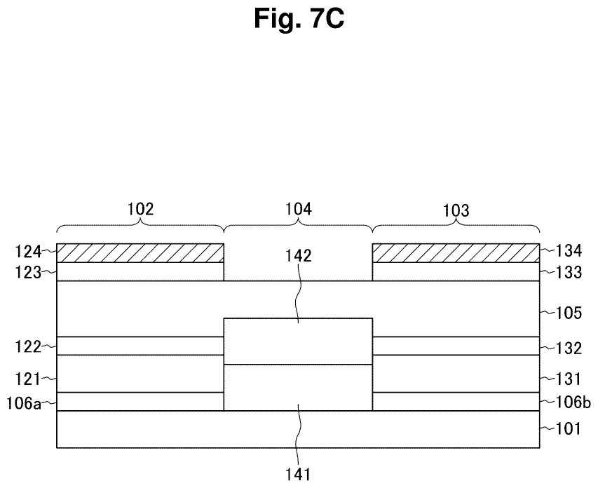

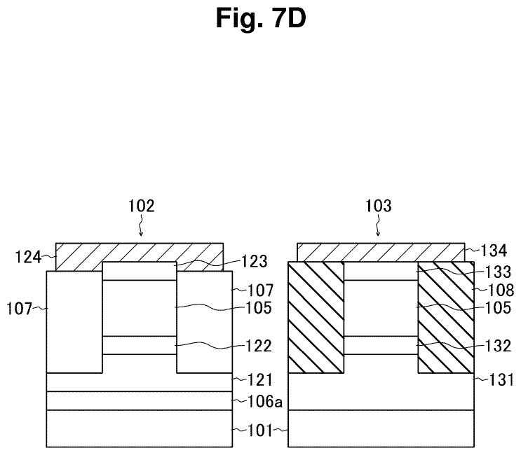

Next, another manufacturing method of a semiconductor device according to an embodiment of the present invention will be described with reference to FIGS. 7A to 7D.

In this manufacturing method, first, similarly to the manufacturing method described above with reference to FIGS. 6A to 6H, each portion of the first optical active element 102, the second optical active element 103, and the optical waveguide 104 is formed in a ridge waveguide structure. Thereafter, as illustrated in FIGS. 7A and 7B, in a region other than the second optical active element 103 (the first optical active element 102 and the optical waveguide 104), the InP as a semi-insulating material is crystal-regrown on the first lower semiconductor layer 121 and the third lower semiconductor layer 141 left on both sides of the ridge waveguide structure to form the embedding layer 107. At this stage, in the second optical active element 103, the upper side of the second lower semiconductor layer 131 left on both sides of the ridge waveguide structure is opened.

Next, as illustrated in FIGS. 7C and 7D, in the region of the second optical active element 103, the embedded insulating layer 108 made of a low-dielectric constant material is formed on the second lower semiconductor layer 131 left on both sides of the ridge waveguide structure. Thereafter, the first p-electrode 124 is formed on the first contact layer 123, and the second p-electrode 134 is formed on the second contact layer 133. Although not illustrated, a first n-electrode electrically connected to the first lower semiconductor layer 121 is formed, and a second n-electrode electrically connected to the second lower semiconductor layer 131 is formed.

Also in this configuration, the electrical resistance between the p-electrode and the n- electrode of the first optical active element 102 as a laser and the p-electrode and the n-electrode of the second optical active element 103 as an EA modulator is 10 kΩ or more. Electric separation between n-electrodes, which cannot be achieved by elements integrated on a conventional n-substrate, can be achieved. In addition, the optical coupling efficiency of the first optical active element 102 serving as the laser unit and the optical waveguide 104 can be a good value of about 98% in calculation. In addition, since the second optical active element 103 serving as the EA modulator is configured to be embedded with the embedded insulating layer 108 made of a low dielectric constant material, the parasitic capacitance of the element can be reduced as compared with the semiconductor embedded structure, and characteristics excellent in high speed performance are realized.

In also this configuration, as a result of applying the differential modulation signal to the second optical active element 103 serving as the EA modulator of the manufactured semiconductor device, it was confirmed that the stable operation of the first optical active element 102 serving as the laser unit and the clear waveform opening of the second optical active element 103 reflected the high electrical resistance described above.

According to embodiments of the present invention as described above, the first optical active element and the second optical active element are formed on the substrate including the semi-insulating compound semiconductor via the etching stop layer, and the optical waveguide functioning as the electrical isolation portion is provided between the first optical active element and the second optical active element, so that the two monolithically integrated optical active elements can be driven by different methods.

Embodiments of the present invention are not limited to the embodiment described above, and it is apparent that various modifications and combinations can be implemented by those skilled in the art without departing from the technical spirit of the present invention.

### Reference Signs List

101 Substrate
102 First optical active element
103 Second optical active element
104 Optical waveguide
105 Upper semiconductor layer
106a First etching stop layer
106b Second etching stop layer
121 First lower semiconductor layer
122 First active layer
123 First contact layer
124 First p-electrode
131 Second lower semiconductor layer
132 Second active layer
133 Second contact layer
134 Second p-electrode
141 Third lower semiconductor layer
142 Third active layer

1-4. (canceled)

5. A semiconductor device comprising:
a substrate made of a semi-insulating compound semiconductor;
a first optical active element including a first etching stop layer on the substrate, a first lower semiconductor layer of a first conductivity type on the first etching stop layer, a first active layer on the first lower semiconductor layer, and a first upper semiconductor layer of a second conductivity type on the first active layer;
a second optical active element on the substrate, the second optical active element including a second etching stop layer on the substrate apart from the first etching stop layer, a second lower semiconductor layer of a first conductivity type, a second active layer on the second lower semiconductor layer, and a second upper semiconductor layer of the second conductivity type on the second active layer; and
an optical waveguide between the first optical active element and the second optical active element, the optical waveguide including a semi-insulating or undoped third lower semiconductor layer, a third active layer on the third lower semiconductor layer, and a third upper semiconductor layer of the second conductivity type on the third active layer, electrically isolating and optically connecting the first optical active element and the second optical active element.

6. The semiconductor device according to claim 5, wherein
a thickness of the third active layer is equal to or larger than thicknesses of the first active layer and the second active layer, and
a total thickness of the third lower semiconductor layer and the third active layer is equal to or larger than a total thickness of the first etching stop layer, the first lower semiconductor layer, and the first active layer, and a total thickness of the second etching stop layer, the second lower semiconductor layer, and the second active layer.

7. The semiconductor device according to claim 6, wherein
a width of the third active layer which is perpendicular to a waveguide direction of the third active layer is equal to or larger than respective widths of the first active layer and the second active layer which are perpendicular to the waveguide direction.

8. The semiconductor device according to claim 5, wherein
the first optical active element is DC-driven, and
in the second optical active element, a differential modulation signal is applied between the second lower semiconductor layer and the upper semiconductor layer in a region of the second optical active element.

9. The semiconductor device according to claim 6, wherein
the first optical active element is DC-driven, and
in the second optical active element, a differential modulation signal is applied between the second lower semiconductor layer and the upper semiconductor layer in a region of the second optical active element.

10. The semiconductor device according to claim 7, wherein
the first optical active element is DC-driven, and
in the second optical active element, a differential modulation signal is applied between the second lower semiconductor layer and the upper semiconductor layer in a region of the second optical active element.

11. The semiconductor device according to claim 5, wherein
the first optical active element is a DC-driven semiconductor laser, and
the second optical active element is a modulator in which a differential modulation signal is applied between the second lower semiconductor layer and the upper semiconductor layer in a region of the second optical active element.

12. The semiconductor device according to claim 6, wherein
the first optical active element is a DC-driven semiconductor laser, and
the second optical active element is a modulator in which a differential modulation signal is applied between the second lower semiconductor layer and the upper semiconductor layer in a region of the second optical active element.

13. The semiconductor device according to claim 7, wherein
the first optical active element is a DC-driven semiconductor laser, and
the second optical active element is a modulator in which a differential modulation signal is applied between the second lower semiconductor layer and the upper semiconductor layer in a region of the second optical active element.

14. The semiconductor device according to claim 5, wherein
the first upper semiconductor layer, the second upper semiconductor layer and the third upper semiconductor layer are as a single layer which is a cladding layer in the first optical active element, the second optical active element and the optical waveguide.

15. A semiconductor device comprising:
a semi-insulating compound semiconductor substrate;
a first optical active element on the substrate, the first optical active element comprising:
a first etching stop layer on the substrate,
a first lower semiconductor layer of a first conductivity type on the first etching stop layer,
a first active layer on the first lower semiconductor layer, and
a first upper semiconductor layer of a second conductivity type on the first active layer;
a second optical active element on the substrate, the second optical active element comprising:
a second etching stop layer on the substrate and spaced apart from the first etching stop layer,
a second lower semiconductor layer of the first conductivity type on the second etching stop layer,
a second active layer on the second lower semiconductor layer, and
a second upper semiconductor layer of the second conductivity type on the second active layer; and
an optical waveguide between the first and second optical active elements, the optical waveguide comprising:
a third lower semiconductor layer in direct contact with the substrate,
a third active layer on the third lower semiconductor layer, and
a third upper semiconductor layer of the second conductivity type on the third active layer,
wherein the third lower semiconductor layer is semi-insulating or undoped, and
wherein the optical waveguide electrically isolates and optically connects the first and second optical active elements.

16. The semiconductor device of claim 15, wherein:
the first optical active element is configured to be DC-driven, and
the second optical active element is configured to receive a differential modulation signal between its second lower semiconductor layer and second upper semiconductor layer.

17. The semiconductor device of claim 15, wherein:
the first optical active element comprises a semiconductor laser, and
the second optical active element comprises an electroabsorption modulator.

18. The semiconductor device of claim 15, wherein:
a thickness of the third active layer is equal to or larger than thicknesses of the first active layer and the second active layer, and
a total thickness of the third lower semiconductor layer and the third active layer is equal to or larger than a total thickness of the first etching stop layer, the first lower semiconductor layer, and the first active layer, and a total thickness of the second etching stop layer, the second lower semiconductor layer, and the second active layer.

19. The semiconductor device of claim 15, wherein:
a width of the third active layer perpendicular to a waveguide direction is equal to or larger than respective widths of the first active layer and the second active layer perpendicular to the waveguide direction, and
the first upper semiconductor layer, the second upper semiconductor layer and the third upper semiconductor layer being a single continuous layer.
